(19) United States
(12) Patent Application Publication
(10) Pub. No.: US 2026/0114172 A1
(43) Pub. Date: Apr. 23, 2026

(54) METHOD FOR MANUFACTURING PEROVSKITE PHOTOVOLTAIC CELL AND PEROVSKITE PHOTOVOLTAIC CELL

(71) Applicant: TOYOTA JIDOSHA KABUSHIKI KAISHA, Toyota-Shi (JP)

(72) Inventor: Hirofumi IISAKA, Nagoya-shi (JP)

(73) Assignee: TOYOTA JIDOSHA KABUSHIKI KAISHA, Toyota-Shi (JP)

(21) Appl. No.: 19/337,529

(22) Filed: Sep. 23, 2025

(30) Foreign Application Priority Data
Oct. 23, 2024 (JP) 2024-186386

(51) Int. Cl. H10K 71/12; C23C 18/02; H10K 30/30; H10K 30/50; H10K 85/50

(52) U.S. Cl. CPC H10K 71/12; C23C 18/02; H10K 30/30; H10K 30/50; H10K 85/50

(57) ABSTRACT

The present disclosure provides means for manufacturing a perovskite photovoltaic cell with high conversion efficiency and high durability. One aspect of the present disclosure is a method for manufacturing a perovskite photovoltaic cell including: an application step of applying a precursor solution on a carrier transport layer, the precursor solution including a precursor substance that generates a perovskite-type crystal, an additive represented by Formula (I), and a solvent; and a heating step of performing a heat treatment on a precursor layer obtained in the application step to form a photoelectric conversion layer including a perovskite film. Another aspect of the present disclosure relates to a perovskite photovoltaic cell.

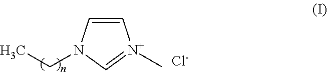

### CROSS REFERENCE TO RELATED APPLICATIONS

The present application claims priority from Japanese patent application JP 2024-186386 filed on Oct. 23, 2024, the entire content of which is hereby incorporated by reference into this application.

### BACKGROUND

### Technical Field

The present disclosure relates to a method for manufacturing a perovskite photovoltaic cell and a perovskite photovoltaic cell.

### Background Art

In recent years, the development of perovskite photovoltaic cells have been underway as a technique for achieving carbon neutrality. The perovskite photovoltaic cell has a perovskite film including a perovskite-type crystal as a photoelectric conversion layer.

For example, Japanese Patent No. 6501303 discloses a method for manufacturing a fine particle perovskite film that is obtainable by applying and drying a solution obtained by dissolving a precursor substance that generates a perovskite-type crystal and an ionic liquid in a solvent, and thereafter, performing an annealing treatment. Japanese Patent No. 6501303 also discloses a method for manufacturing a functional device, such as a perovskite photovoltaic cell, that uses the fine particle perovskite film manufactured in the above-described method.

### SUMMARY

For example, Japanese Patent No. 6501303 discloses that in the method disclosed in the Japanese Patent No. 6501303, a perovskite-type crystal is miniaturized into nano-level fine particles, and an optical property and the like can be improved. However, durability under an environment with high temperature and high humidity is not examined in Japanese Patent No. 6501303. Thus, the conventional perovskite photovoltaic cell has had a problem from the view point of providing both conversion efficiency and durability.

Accordingly, the present disclosure provides means for manufacturing a perovskite photovoltaic cell with high conversion efficiency and high durability.

The inventor has examined various means for solving the above-described problems. The inventor has found that the conversion efficiency and the durability of a photoelectric conversion layer can be improved by forming a perovskite film, which is used as the photoelectric conversion layer of a perovskite photovoltaic cell, using a precursor solution including a certain additive. The inventor has completed the present disclosure on the basis of the above-described knowledge.

In other words, the present disclosure includes the following aspects and embodiments.

### Embodiment 1

1. A method for manufacturing a perovskite photovoltaic cell comprising:
an application step of applying a precursor solution on a carrier transport layer, the precursor solution including a precursor substance that generates a perovskite-type crystal, an additive represented by Formula (I):

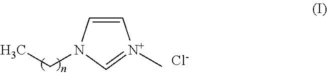

wherein n is an integer equal to or more than 6, and
a solvent; and
a heating step of performing a heat treatment on a precursor layer obtained in the application step to form a photoelectric conversion layer including a perovskite film.

### Embodiment 2

2. The method according to Embodiment 1,
wherein n is an integer equal to or more than 6 and equal to or less than 11.

### Embodiment 3

3. The method according to Embodiment 1 or 2,
wherein n is 7.

### Embodiment 4

4. The method according to any one of Embodiments 1 to 3,
wherein the precursor substance is a mixture of a halogenated organic amine, a halogenated amidinium, and a metal halide.

### Embodiment 5

5. The method according to Embodiment 4,
wherein the precursor substance is a mixture of methylammonium iodide, formamidinium iodide, cesium iodide, and lead iodide.

### Embodiment 6

6. A perovskite photovoltaic cell at least comprising:
a photoelectric conversion layer including a perovskite film including a perovskite-type crystal; and
two carrier transport layers arranged on both surfaces of the photoelectric conversion layer,
wherein the perovskite film included in the photoelectric conversion layer has orientation indices on at least a (100) plane, a (002) plane, and a (220) plane among orientation indices in an X-ray diffraction (XRD) calculated using Wilson's method of 1 or more.

The present disclosure allows for providing means for manufacturing a perovskite photovoltaic cell with high conversion efficiency and high durability.

### BRIEF DESCRIPTION OF THE DRAWINGS

FIG. 1 is a cross-sectional view illustrating an embodiment of a perovskite photovoltaic cell manufactured by a method of one aspect of the present disclosure;

FIG. 2 is a graph showing a relationship between the carbon number of a side-chain alkyl group in an additive used in manufacturing a perovskite film in an example and a melting point. In the drawing, the horizontal axis indicates the carbon number of the side-chain alkyl group, and the vertical axis indicates the melting point (K). In the additive represented by Formula (I), the side-chain alkyl group is represented by H₃C—(CH₂)ₙ—. In view of this, the carbon number of the side-chain alkyl group is n+1;

FIG. 3 is a graph showing a relationship between the carbon number of the side-chain alkyl group in the additive used in manufacturing the perovskite film in the example and an average particle size of perovskite particles included in the manufactured perovskite film. In the drawing, the horizontal axis indicates the carbon number of the side-chain alkyl group, and the vertical axis indicates the average particle size (μm) of the perovskite particles;

FIG. 4 is scanning electron microscope (SEM) photographs of perovskite films manufactured in the example. In the drawing, A is a SEM photograph of a perovskite film manufactured using a precursor solution including an additive having 8 carbon atoms in the side-chain alkyl group (that is, n is 7), B is a SEM photograph of a perovskite film manufactured using a precursor solution including an additive having 16 carbon atoms in the side-chain alkyl group (that is, n is 15), C is a SEM photograph of a perovskite film manufactured using a precursor solution including an additive having 4 carbon atoms in the side-chain alkyl group (that is, n is 3), D is a SEM photograph of a perovskite film manufactured using a precursor solution including an additive having 6 carbon atoms in the side-chain alkyl group (that is, n is 5), and E is a SEM photograph of a control perovskite film manufactured using a precursor solution not including an additive;

FIG. 5 is SEM photographs of perovskite films treated in a high temperature test. In the drawing, A is a SEM photograph of a perovskite film manufactured using a precursor solution including an additive having 8 carbon atoms in the side-chain alkyl group (that is, n is 7), B is a SEM photograph of a perovskite film manufactured using a precursor solution including an additive having 16 carbon atoms in the side-chain alkyl group (that is, n is 15), C is a SEM photograph of a perovskite film manufactured using a precursor solution including an additive having 4 carbon atoms in the side-chain alkyl group (that is, n is 3), and D is a SEM photograph of a perovskite film manufactured using a precursor solution including an additive having 6 carbon atoms in the side-chain alkyl group (that is, n is 5);

FIG. 6 is a graph showing an orientation index of each plane index in an X-ray diffraction (XRD) calculated using Wilson's method. In the drawing, the horizontal axis indicates the plane index, and the vertical axis indicates the orientation index of each plane index;

FIG. 7 is a graph showing a relationship between the carbon number of the side-chain alkyl group in the additive used in manufacturing the perovskite film in the example and an XRD area ratio (PbI₂/PVK) of a (001) plane peak of lead iodide (PbI₂) and a (110) plane peak of an α phase of a perovskite compound (PVK) included in the manufactured perovskite film. In the drawing, the horizontal axis indicates the carbon number of the side-chain alkyl group, and the vertical axis indicates the XRD area ratio (PbI₂/PVK); and

FIG. 8 is a graph showing a relationship between a temperature of a heat treatment test of the perovskite film manufactured using no additive (comparative) or an additive having 8 carbon atoms in the side-chain alkyl group (that is, n is 7) in the example and an XRD area ratio (PbI₂/PVK) of the (001) plane peak of the PbI₂ and the (110) plane peak of the α phase of the PVK included in the perovskite film after the treatment. In the drawing, the horizontal axis indicates the temperature (° C.) of the heat treatment test, and the vertical axis indicates the XRD area ratio (PbI₂/PVK).

### DETAILED DESCRIPTION

The following describes embodiments of the present disclosure in detail.

An aspect of the present disclosure relates to a method for manufacturing a perovskite photovoltaic cell.

In each aspect of the present disclosure, the perovskite photovoltaic cell means a dye-sensitized solar cell that at least includes a photoelectric conversion layer including a perovskite film and two carrier transport layers arranged on both surfaces of the photoelectric conversion layer. In the perovskite photovoltaic cell, one of the two carrier transport layers is a hole transport layer, and the other is an electron transport layer.

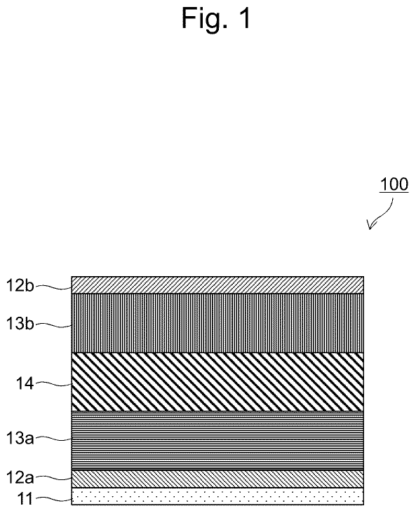

FIG. 1 illustrates a cross-sectional view showing one embodiment of a perovskite photovoltaic cell manufactured by the method of the aspect. As illustrated in FIG. 1, a perovskite photovoltaic cell 100 at least includes a substrate 11, a first electrode 12a arranged on an upper surface of the substrate 11, a first carrier transport layer 13a arranged on an upper surface of the first electrode 12a, a photoelectric conversion layer 14 arranged on an upper surface of the first carrier transport layer 13a, a second carrier transport layer 13b arranged on an upper surface of the photoelectric conversion layer 14, and a second electrode 12b arranged on an upper surface of the second carrier transport layer 13b. For example, when the perovskite photovoltaic cell 100 is an n-i-p planar structure, the substrate 11 is a transparent substrate made of a glass, a resin, or the like, the first electrode 12a is a transparent electrode, the first carrier transport layer 13a is an electron transport layer, the second carrier transport layer 13b is a hole transport layer, and the second electrode 12b is a backside electrode. Alternatively, when the perovskite photovoltaic cell 100 is a p-i-n planar structure, the substrate 11 is a transparent substrate made of a glass, a resin, or the like, the first electrode 12a is a transparent electrode, the first carrier transport layer 13a is a hole transport layer, the second carrier transport layer 13b is an electron transport layer, and the second electrode 12b is a backside electrode.

The perovskite film included in the photoelectric conversion layer usually includes a perovskite-type crystal. The perovskite-type crystal usually is made of a perovskite compound having a composition formula of ABX₃ (wherein A represents a monovalent cation, B represents a divalent cation, and X represents a monovalent anion), and has a unit cell of a cubic crystal system.

Examples of the monovalent cation A constituting the perovskite-type crystal can include, for example, monovalent organic ammonium ions, monovalent amidinium-based ions, and monovalent metallic ions. The monovalent organic ammonium ion may be CH₃NH₃⁺ (a methylammonium ion, hereinafter also referred to as “MA”), C₂H₅NH₃⁺, C₃H₇NH₃⁺, or C₄H₉NH₃⁺. The monovalent amidinium-based ion may be HC (NH₂)₂⁺ (a formamidinium ion, hereinafter also referred to as “FA”). The monovalent metallic ion may be a rubidium ion (Rb⁺) or a cesium ion (Cs⁺). The monovalent cation A may be only one cation exemplarily described above, or may be a combination of two or more cations exemplarily described above. The monovalent cation A may be only MA, FA, or Cs⁺, a combination of MA, FA, and Cs⁺, or a combination of MA, FA, and/or Cs⁺ and another cation, and may be a combination of MA, FA, and Cs⁺.

Examples of the divalent cation B constituting the perovskite-type crystal can include, for example, divalent metallic ions. The divalent metallic ion may be a lead ion (Pb²⁺) or a tin ion (Sn²⁺). The divalent cation B may be only one cation exemplarily described above, or may be a combination of two or more cations exemplarily described above. The divalent cation B may be Pb²⁺.

Examples of the monovalent anion X constituting the perovskite-type crystal can include, for example, halogen ions. The halogen ion may be a fluoride ion (F⁻), a chloride ion (Cl⁻), a bromide ion (Br⁻), or an iodide ion (I⁻). The halogen ion may be only one anion exemplarily described above, or may be a combination of two or more anions exemplarily described above. The monovalent anion X may be I⁻, Cl⁻, or Br⁻, and may be I⁻.

In the perovskite photovoltaic cell manufactured by the method of the aspect, the inclusion of the perovskite-type crystal having the feature described above in the perovskite film included in the photoelectric conversion layer is, for example, confirmable by analyzing the perovskite film included in the photoelectric conversion layer by scanning electron microscope-energy dispersive X-ray spectroscopy (SEM-EDX) or X-ray diffraction (XRD).

The method of the aspect at least includes an application step and a heating step. The application step and the heating step are steps for forming the photoelectric conversion layer. The method of the aspect may include a material preparation step and an electrode and carrier transport layer formation step as desired. The electrode and carrier transport layer formation step is executable by applying a formation technique of the electrode and the carrier transport layer usually executed in the technical field. The following describes the application step and the heating step, and the material preparation step for executing these steps in detail.

### [1: Material Preparation Step]

The step includes preparation of a precursor solution of a perovskite film used in the application step and the heating step for forming a photoelectric conversion layer. The precursor solution prepared in the step usually at least includes a precursor substance that generates a perovskite-type crystal, an additive, and a solvent.

The respective components in the precursor solution may be prepared by purchasing commercial products or the like, or may be prepared by self-synthesizing them.

The respective components in the precursor solution will be described in further detail below.

### [2: Application Step]

The step includes applying the precursor solution including the precursor substance that generates the perovskite-type crystal, the additive, and the solvent on a carrier transport layer. The step allows a precursor layer including the precursor substance, the additive, and the solvent to be formed on a surface of the carrier transport layer.

The precursor substance that generates the perovskite-type crystal is appropriately selectable on the basis of the composition of the perovskite-type crystal described above. For example, when the monovalent cation A constituting the perovskite-type crystal is a monovalent organic ammonium ion and a monovalent amidinium-based ion, the divalent cation B is a divalent metallic ion, and the monovalent anion X is a halogen ion, a mixture of a halogenated organic amine, a halogenated amidinium, and a metal halide may be used for the precursor substance. For example, when the monovalent cation A constituting the perovskite-type crystal is a combination of MA, FA, and Cs⁺, the divalent cation B is Pb²⁺, and the monovalent anion X is I⁻, the precursor substance may be a mixture of methylammonium iodide (MAI), formamidinium iodide (FAI), cesium iodide (CsI), and lead iodide (PbI₂).

In the method of the aspect, the additive is a compound represented by Formula (I):

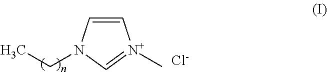

The compound represented by Formula (I) has properties as an ionic liquid. The perovskite film obtained by executing the step using the precursor solution including the compound represented by Formula (I) as the additive has a large particle size of the perovskite-type crystal included in the perovskite film and high durability under a high temperature condition compared with a conventional perovskite film obtained using a precursor solution not including an additive.

In Formula (I), n is an integer equal to or more than 6. n may be an integer equal to or more than 6 and equal to or less than 11, and n may be 7. When n is an integer less than 6 and/or an integer exceeding 11, there is not only the possibility of the melting point of the compound represented by Formula (I) exceeding a desired upper-limit value, but also the possibility of particle sizes of perovskite particles included in the perovskite film manufactured using the precursor solution including the compound as an additive decreasing and/or becoming uneven. Accordingly, executing the step using the precursor solution including the compound represented by Formula (I) having the feature exemplarily described above as an additive allows for manufacturing a perovskite photovoltaic cell with high conversion efficiency and high durability.

The melting point of the compound represented by Formula (I) is usually 150° C. or more, and in particular, 170° C. or more. The melting point of the compound represented by Formula (I) may be 250° C. or less or in a range of 150° C. to 250° C., and may be 200° C. or less or in a range of 150° C. to 200° C. When the melting point of the compound represented by Formula (I) exceeds the upper-limit value, it is possible that the particle sizes of the perovskite particles included in the perovskite film manufactured using the precursor solution including the compound as an additive decrease and/or become uneven. Accordingly, executing the step using the precursor solution including the compound represented by Formula (I) having the melting point in the range exemplarily described above as an additive allows for manufacturing a perovskite photovoltaic cell with high conversion efficiency and high durability.

In the perovskite photovoltaic cell, the larger the particle size of the perovskite-type crystal included in the perovskite film used as a photoelectric conversion layer is, the smaller the area of the grain boundary high in electrical resistance becomes. In view of this, the perovskite photovoltaic cell having the perovskite film including the perovskite-type crystal with a large particle size as a photoelectric conversion layer is high in light-energy conversion efficiency. The perovskite-type crystal included in the perovskite film may be hydrolyzed if it comes into contact with water vapor. Such a hydrolysis reaction is generally accelerated under a high temperature condition (for example, a temperature equal to or more than 100° C.). In view of this, the higher the durability of the perovskite film used as a photoelectric conversion layer under the high temperature condition is, the higher the durability of the perovskite photovoltaic cell becomes. Accordingly, executing the step using the precursor solution including the additive exemplarily described above allows for manufacturing a perovskite photovoltaic cell with high conversion efficiency and high durability.

Examples of the solvent can include, for example, aprotic polar solvents, such as amide-type solvents, lactone-type solvents, lactam-type solvents, and sulfoxide-type solvents. The solvent may be N,N-dimethylformamide (DMF), dimethylsulfoxide (DMSO), Y-butyrolactone, or N-methylpyrrolidone, or a mixture thereof, and may be a mixture of DMF and DMSO. Executing the step using the precursor solution including the solvent exemplarily described above allows the precursor solution to be uniformly applied.

In the step, means for applying the precursor solution over the carrier transport layer is not specifically limited, and various means usually used in the technical field is applicable. Examples of the application means can include, for example, a blade coating method, a die coating method, an inkjet method, a spraying method, and a spin coating method. Any means exemplarily described above is applicable to the step.

The step may further include application of a poor solvent on the precursor layer as desired. In the embodiment, the poor solvent means a solvent having low solubility of the perovskite-type crystal compared with the solvent included in the precursor solution. The poor solvent may be an aliphatic hydrocarbon, an aromatic hydrocarbon, an alcohol, an ether, or a fatty acid, may be dichloromethane, chloroform, toluene, benzene, chlorobenzene, tetralin, propanol, butanol, diethyl ether, tetrahydrofuran, or acetic acid, or a mixture thereof, and may be chlorobenzene. In the case of the embodiment, for the means for applying the poor solvent on the precursor layer, means similar to the means for applying the precursor solution on the carrier transport layer exemplarily described above is simply appropriately applied. Executing the step using the poor solvent exemplarily described above accelerates a growth of the perovskite-type crystal, thereby allowing for improved conversion efficiency of the perovskite photovoltaic cell obtained as the result.

### [3: Heating Step]

The step includes performing a heat treatment on the precursor layer obtained through the application step. The step allows for performing an annealing treatment on the precursor layer to form the photoelectric conversion layer including the perovskite film.

In the step, a temperature of the heat treatment may be in a range of 70° C. to 200° C. The period of the heat treatment may be in a range of 1 minute to 60 minutes. Executing the step under the condition exemplarily described above allows for performing the annealing treatment on the precursor layer to accelerate the growth of the perovskite-type crystal.

The step may further include performing a drying treatment on the precursor layer as desired. In the embodiment, the drying treatment may be executed as the same treatment as the annealing treatment, or may be executed as another treatment. Examples of the means for the drying treatment can include, for example, a heat drying treatment, a vacuum drying treatment, and a spraying treatment of a dry gas. When the heat drying treatment is applied, the heat drying treatment may be executed as the same treatment as the annealing treatment in the step.

The perovskite film included in the photoelectric conversion layer of the perovskite photovoltaic cell manufactured or can be manufactured by the method of the aspect described above may have a fine structure without pinholes, and may have a flat surface without pinholes and has perovskite particles having large particle sizes densely filling the inside in a gapless manner. In the photoelectric conversion layer of the perovskite photovoltaic cell, lattice defects of impurities present on crystal surfaces and interfaces (grain boundaries) between crystal grains act as a trapping center (trap) of electrons and holes to block charge transfer, thus possibly causing energy loss. Here, when the perovskite particles included in the photoelectric conversion layer have large particle sizes, specific surface areas of the perovskite particles decrease, thus, areas of the grain boundaries also possibly decrease, and as the result, an amount of the lattice defects also possibly decrease. When the particle sizes of the perovskite particles are equal to or more than a film thickness of the perovskite film, the grain boundaries can be generated only in a film thickness direction of the perovskite film, but cannot be generated in a plane direction of the perovskite film. In view of this, when the particle sizes of the perovskite particles are equal to or more than the film thickness of the perovskite film, the possibility that the lattice defects in the grain boundaries act as the trapping center of electrons and holes to block charge transfer, thus causing energy loss can be reduced. Furthermore, when the perovskite particles included in the photoelectric conversion layer have large particle sizes, the areas of grain boundaries decrease, thus, the perovskite film can be a polycrystal film, and therefore, recombination of electric charge can be reduced.

The film thickness of the perovskite film included in the photoelectric conversion layer of the perovskite photovoltaic cell manufactured or can be manufactured by the method of the aspect described above is usually 2.0 μm or less, and is, for example, 1.8 μm or less, and in particular, 1.0 μm or less. The film thickness of the perovskite film may be in a range of 0.5 μm to 2.0 μm, may be in a range of 0.5 μm to 1.8 μm, and may be in a range of 0.5 μm to 1.0 μm. As described above, the surface structure and the film thickness of the perovskite film included in the photoelectric conversion layer of the perovskite photovoltaic cell are closely related to the light-energy conversion efficiency of the perovskite photovoltaic cell. Accordingly, the perovskite photovoltaic cell including the perovskite film having the film thickness in the range exemplarily described above in the photoelectric conversion layer is allowed to have high conversion efficiency of light energy.

The particle sizes of the perovskite particles present in the perovskite film included in the photoelectric conversion layer of the perovskite photovoltaic cell manufactured or can be manufactured by the method of the aspect described above is usually 2.0 μm or less, and in particular, 1.8 μm or less. The particle sizes of the perovskite particles may be in a range of 1.2 μm to 2.0 μm, may be in a range of 1.3 μm to 2.0 μm, and may be in a range of 1.4 μm to 1.8 μm. As described above, the particle sizes of the perovskite particles present in the perovskite film included in the photoelectric conversion layer of the perovskite photovoltaic cell is closely related to the light-energy conversion efficiency of the perovskite photovoltaic cell. Accordingly, the perovskite particles having the particle sizes in the range exemplarily described above being present in the perovskite film allows the perovskite photovoltaic cell including the perovskite film in the photoelectric conversion layer to have high conversion efficiency of light energy.

A surface condition of the perovskite film included in the photoelectric conversion layer of the perovskite photovoltaic cell manufactured or can be manufactured by the method of the aspect described above and the particle sizes of the perovskite particles present in the perovskite film are observable and measurable in the following procedure using, for example, a scanning electron microscope-energy dispersive X-ray spectroscopic analyzer (SEM-EDX) or a scanning electron microscope (SEM). Using the SEM-EDX or SEM, the surface condition of the perovskite film is observed. Using image processing software, particle sizes of the plurality of perovskite particles are measured in a SEM photograph of each perovskite film, and an average value and a standard deviation thereof are calculated.

The perovskite photovoltaic cell manufactured or can be manufactured by the method of the aspect described above having high conversion efficiency is evaluable by, for example, using the method described above, observing and measuring the surface condition of the perovskite film included in the photoelectric conversion layer of the perovskite photovoltaic cell and the particle sizes of the perovskite particles present in the perovskite film.

The perovskite photovoltaic cell manufactured or can be manufactured by the method of the aspect described above having high durability is evaluable by, for example, using the perovskite film included in the photoelectric conversion layer of the perovskite photovoltaic cell executing a high temperature test in the following procedure. The perovskite film is exposed for a predetermined period in a high temperature test condition (for example, 120° C.). Thereafter, using the SEM-EDX or SEM, the surface condition of the perovskite film (for example, presence/absence of vacancy caused by the perovskite particles pyrolyzed by the treatment of the high temperature test) is observed. Alternatively, using the XRD, crystalline structures of the perovskite particles included in the perovskite film after the exposure are observed. An XRD area ratio (PbI₂/PVK) of a (001) plane peak of PbI₂ and a (110) plane peak of an α phase of a PVK in the XRD is calculated, and the XRD area ratio being a desired value described below is confirmed.

The fact that the perovskite photovoltaic cell has been manufactured by the method of the aspect described above is, for example, confirmable by identifying the compound represented by Formula (I) in the perovskite film included in the photoelectric conversion layer of the perovskite photovoltaic cell by an instrumental analysis, such as an XRD, a nuclear magnetic resonance spectrum (NMR), or a mass spectrum (MS).

Another aspect of the present disclosure relates to a perovskite photovoltaic cell manufactured or can be manufactured by the method of the aspect described above. The perovskite photovoltaic cell of the aspect usually at least includes a photoelectric conversion layer including a perovskite film including perovskite-type crystals, and two carrier transport layers arranged on both surfaces of the photoelectric conversion layer.

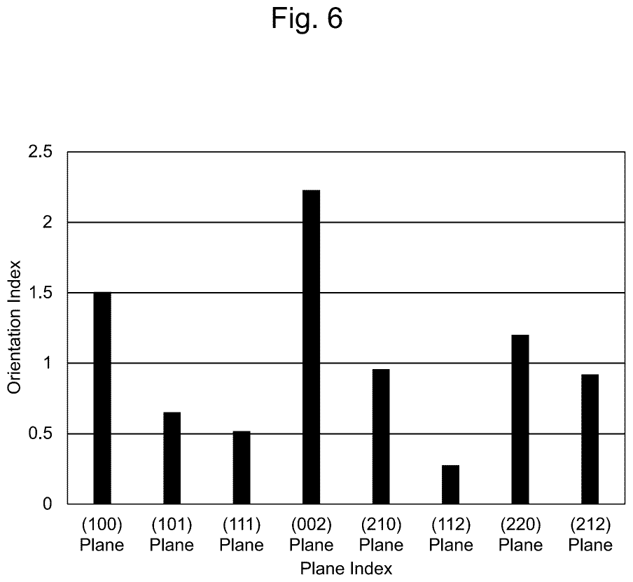

In the perovskite photovoltaic cell of the aspect, the perovskite film included in the photoelectric conversion layer usually has orientation indices on at least a (100) plane, a (002) plane, and a (220) plane among the orientation indices in the XRD calculated using the Wilson's method of 1 or more (FIG. 6). In the crystal, the orientation index in the XRD calculated using the Wilson's method is known to be an indicator of high crystallinity (Hiroshi Takada et al., Journal of the Japan Institute of Metals and Materials, Vol. 55, No. 12 (1991) 1368-1374). For example, when the orientation indices of the crystal are all 1, the crystal is estimated to be non-oriented. When there is a direction in which the orientation index of the crystal has a value exceeding 1, the crystal is estimated to have an orientation in the direction. When there are a plurality of directions in which the orientation index of the crystal has a value exceeding 1, the crystal is estimated to have an orientation in the direction with the largest value among all.

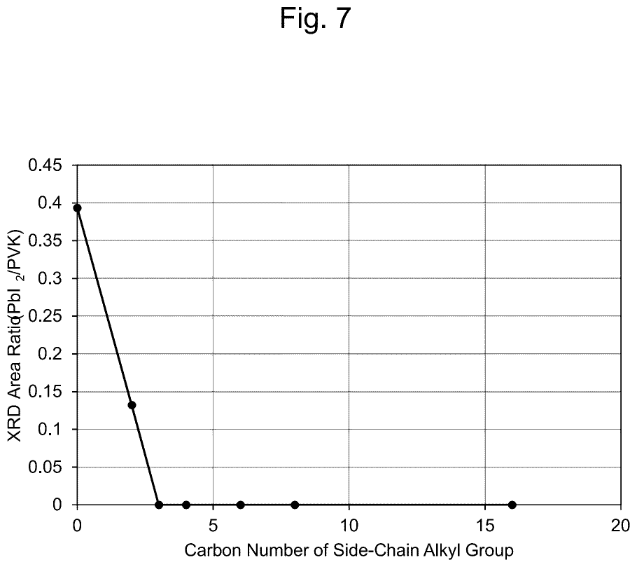

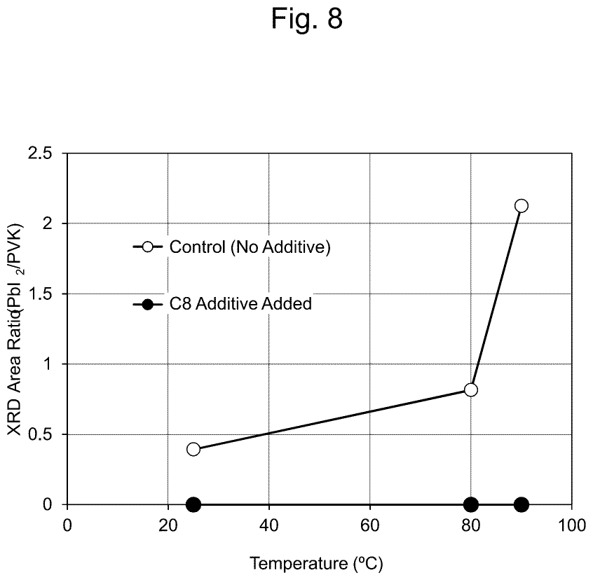

In the perovskite photovoltaic cell of the aspect, the perovskite film included in the photoelectric conversion layer has the XRD area ratio (PbI₂/PVK) of the (001) plane peak of the lead iodide (PbI₂) and the (110) plane peak of the α phase of the perovskite compound (PVK) in the XRD of usually 0.1 or less, and in particular, 0 (FIG. 7). In particular, in the perovskite photovoltaic cell of the aspect, the perovskite film included in the photoelectric conversion layer has the XRD area ratio (PbI₂/PVK) of usually 0.3 or less, and in particular, 0 (FIG. 8) even after the heat treatment (for example, exposure for approximately 100 hours at 100° C. or less, in particular, 90° C. or less). As will be described in Example, the XRD area ratio (PbI₂/PVK) of the (001) plane peak of the PbI₂ and the (110) plane peak of the α phase of the PVK included in the perovskite film has a constant correlation relationship with an amount of the PbI₂ generated by decomposition of the perovskite compound, and therefore, can be a deterioration index of the perovskite film or the perovskite compound used in the perovskite photovoltaic cell, but can also be a performance index of the perovskite photovoltaic cell. Accordingly the perovskite photovoltaic cell of the aspect having the XRD area ratio (PbI₂/PVK) of the perovskite film included in the photoelectric conversion layer of the value in the range exemplarily described above allows not only the perovskite film to provide high light-energy conversion efficiency, but also to provide high durability under a high temperature condition.

As described in detail above, the method of the aspect allows for manufacturing a perovskite photovoltaic cell having high conversion efficiency and high durability. The perovskite photovoltaic cell manufactured or can be manufactured by the method of the aspect has high conversion efficiency of light energy in the perovskite film used as the photoelectric conversion layer, and high durability of the perovskite film under a high temperature condition. In view of this, the perovskite photovoltaic cell manufactured or can be manufactured by the method of the aspect is appropriate for a usage used under an outdoor environment where the perovskite photovoltaic cell is continuously exposed in a high temperature environment (for example, a temperature equal to or more than 100° C.), for example an automotive usage, such as an automobile, or an installation usage onto a roof, a wall surface, or the like of a construction. The perovskite photovoltaic cell manufactured or can be manufactured by the method of the aspect allows for providing high conversion efficiency and high durability over a long period of time even when it is applied to the usage exemplarily described above.

### Example

### <I: Manufacturing of Perovskite Film>

### [I-1: Preparation of Precursor Solution]

A mixture of methylammonium iodide (MAI), formamidinium iodide (FAI), cesium iodide (CsI), and lead iodide (PbI₂) (all manufactured by Tokyo Chemical Industry Co., Ltd.) was prepared as a precursor substance that generates perovskite-type crystals, a compound represented by Formula (I) (wherein n is an integer equal to or more than 0 and equal to or less than 18) (manufactured by Kanto Chemical Co., Inc.) was prepared as an additive, a mixture (4:1) of N,N-dimethylformamide (DMF) (manufactured by FUJIFILM Wako Pure Chemical Corporation) and dimethylsulfoxide (DMSO) (manufactured by FUJIFILM Wako Pure Chemical Corporation) was prepared as a solvent, and chlorobenzene (manufactured by Sigma Aldrich) was prepared as a poor solvent. The precursor substance and the additive (0.75 mol %) were dissolved in the solvent under the condition of 70° C. and 5 minutes. The solution was further stirred under the condition of 40° C. and 30 minutes, and thus, the precursor solution was prepared. As Comparative Example, a precursor solution without including an additive was prepared.

### [I-2: Film Formation of Perovskite Film]

A precursor solution prepared in I-1 by the spin coating method was dropped on a glass substrate (manufactured by Nippon Sheet Glass Co., Ltd.) cleaned with an isopropanol, thereafter, the glass substrate was rotated at a high speed under the condition of 6000 rpm, and thus, the precursor solution was uniformly applied on the glass substrate. Next, a poor solvent was dropped on the applied precursor solution, thereafter, the glass substrate was rotated at a high speed under the condition of 6000 rpm, and thus, a precursor layer was formed on a surface of the glass substrate (application step). Thereafter, the glass substrate was heated under the condition of 100° C. and 30 minutes on a hot plate, and thus, the precursor layer was dried and underwent the annealing treatment (heating step). Such a treatment removed the solvent and the poor solvent included in the precursor layer, and grew perovskite-type crystals, and thus, a perovskite film ((FA_{0.8}MA_{0.15}Cs_{0.05}) PbI₃) was formed.

### <II: Performance Evaluation of Perovskite Film>

### [II-1: Observation of Perovskite-Type Crystal and Measurement of Particle Size]

Using a scanning electron microscope-energy dispersive X-ray spectroscopic analyzer (SEM-EDX, Nano Shield, manufactured by Hitachi High-Tech Corporation), a surface condition of the manufactured perovskite film was observed. Using image processing software (WinROOF2023, manufactured by Mitani Corporation), particle sizes of a plurality of perovskite particles were measured in SEM photographs (10000 times) of the respective perovskite films, and average values and standard deviations thereof were calculated.

Using an X-ray diffractometer (XRD), the crystalline structure of the perovskite particles included in the manufactured perovskite film were observed. Using the Wilson's method, an orientation index of each plane index in the XRD were calculated (Hiroshi Takada et al., Journal of the Japan Institute of Metals and Materials, Vol. 55, No. 12 (1991) 1368-1374). An XRD area ratio (PbI₂/PVK) of a (001) plane peak of lead iodide (PbI₂) and a (110) plane peak of an α phase of a perovskite compound (PVK) in the XRD was calculated.

### [II-2: Melting Point Measurement Test of Additive]

In order to prepare a precursor solution including an additive that is an ionic liquid, the additive must be dissolved under the dissolution condition (70° C. and 5 minutes) in the procedure in I-1. Therefore, a melting point of the additive was measured by means of a differential scanning calorimetry (Q1000, manufactured by TA Instruments).

### [II-3: Heat Treatment Test]

The manufactured perovskite film was exposed under a high temperature condition (120° C.) for 100 hours. Thereafter, using the SEM-EDX, a surface condition of the perovskite film after the exposure was observed. The manufactured perovskite film was exposed under a normal temperature to high temperature condition (25° C., 80° C., or 90° C.) under an argon atmosphere for 100 hours. Thereafter, using the XRD, the crystalline structure of the perovskite particles included in the perovskite film after the exposure were observed. An XRD area ratio (PbI₂/PVK) of a (001) plane peak of PbI₂ and a (110) plane peak of an α phase of a PVK in the XRD was calculated.

### [II-4: Evaluation Result]

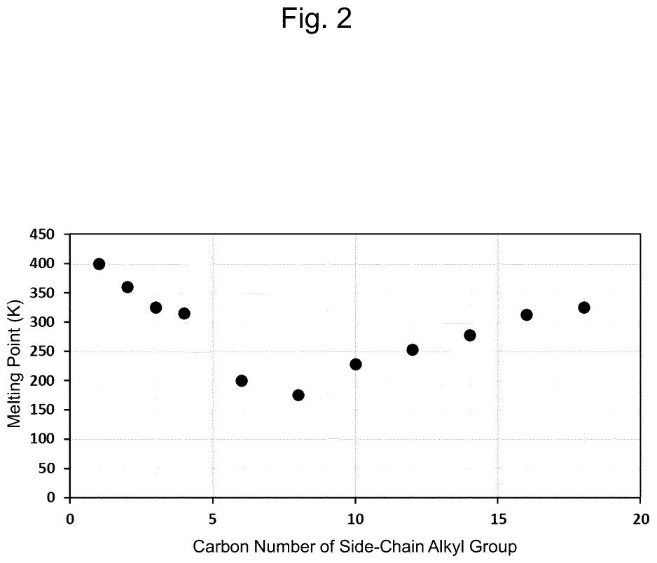

FIG. 2 shows a relationship between the carbon number of a side-chain alkyl group in the additive used in manufacturing the perovskite film and a melting point. In the drawing, the horizontal axis indicates the carbon number of the side-chain alkyl group, and the vertical axis indicates the melting point (K). In the additive represented by Formula (I), the side-chain alkyl group is represented by H₃C—(CH₂)ₙ—. In view of this, the carbon number of the side-chain alkyl group is n+1.

As illustrated in FIG. 2, the additive having 8 carbon atoms in the side-chain alkyl group (that is, n is 7) exhibited the local minimal melting point. In a range of 2 to 8 carbon atoms in the side-chain alkyl group (that is, a range where n is 1 to 7), the melting point lowered in accordance with the increase of the carbon number of the side-chain alkyl group. This is estimated to be caused by the asymmetry of cation in the additive represented by Formula (I) and flexibility of the side-chain alkyl group. On the other hand, in a range of 8 to 16 carbon atoms in the side-chain alkyl group (that is, a range where n is 7 to 15), the melting point elevated in accordance with the increase of the carbon number of the side-chain alkyl group. This is estimated to be caused by an interaction (three-dimensional structural stabilization) of the side-chain alkyl groups between additive molecules represented by a plurality of Formulae (I) forming a crystalline structure in which the side-chain alkyl groups are arranged in parallel.

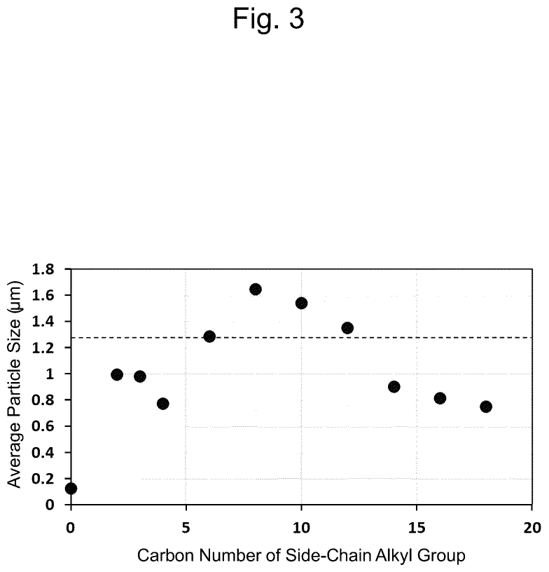

FIG. 3 shows a relationship between the carbon number of the side-chain alkyl group in the additive used in manufacturing the perovskite film and the average particle size of the perovskite particles included in the manufactured perovskite film. In the drawing, the horizontal axis indicates the carbon number of the side-chain alkyl group and the vertical axis indicates the average particle size (μm) of the perovskite particles.

As illustrated in FIG. 3, the perovskite particles included in the perovskite film manufactured using the additive having 8 carbon atoms in the side-chain alkyl group (that is, n is 7) exhibited the average particle size of 1.65±0.604 μm that is a local maximal value. In contrast to this, the perovskite particles included in the perovskite film manufactured using the additive having, for example, 16 carbon atoms, which is more carbon atoms, in the side-chain alkyl group (that is, n is 15) exhibited the average particle size of 0.817±0.256 μm. The perovskite particles included in the perovskite film manufactured using the additive having 6 carbon atoms in the side-chain alkyl group (that is, n is 5) described in Japanese Patent No. 6501303 exhibited the average particle size of 1.29±0.681 μm.

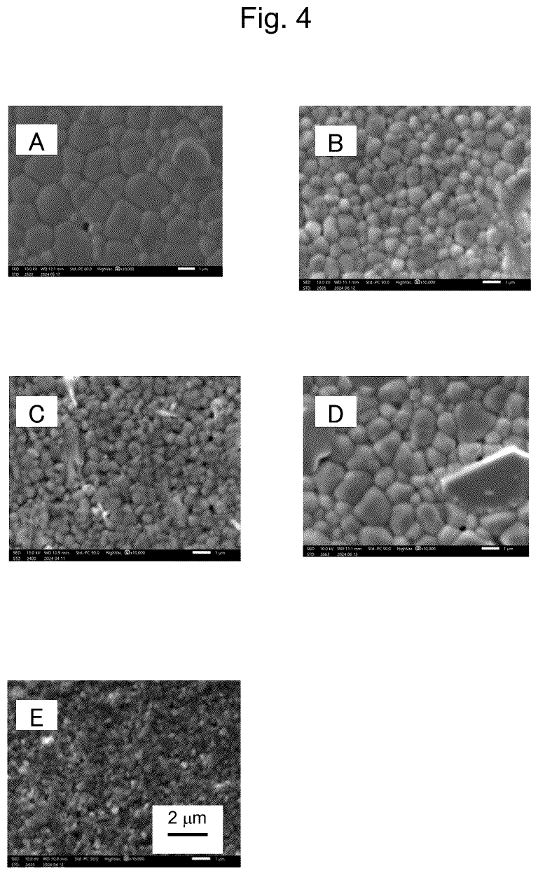

FIG. 4 shows SEM photographs of the manufactured perovskite films. In the drawing, A is a SEM photograph of a perovskite film manufactured using a precursor solution including an additive having 8 carbon atoms in a side-chain alkyl group (that is, n is 7), B is a SEM photograph of a perovskite film manufactured using a precursor solution including an additive having 16 carbon atoms in a side-chain alkyl group (that is, n is 15), C is a SEM photograph of a perovskite film manufactured using a precursor solution including an additive having 4 carbon atoms in a side-chain alkyl group (that is, n is 3), D is a SEM photograph of a perovskite film manufactured using a precursor solution including an additive having 6 carbon atoms in a side-chain alkyl group (that is, n is 5), and E is a SEM photograph of a control perovskite film manufactured using a precursor solution not including an additive.

As illustrated in FIG. 4, the perovskite particles included in the perovskite films manufactured using the precursor solutions including the additives having 7 or more carbon atoms in the side-chain alkyl groups (that is, n is 6 or more) had uniform particle sizes (Panels A and B). In contrast to this, the perovskite particles included in the perovskite films manufactured using the precursor solutions including the additives having less than 7 carbon atoms in the side-chain alkyl groups (that is, n is less than 6), while having larger average particle sizes than those of the perovskite particles included in the control perovskite film (Panel E), had average particle sizes thereof slightly small and were uneven (Panel C and D).

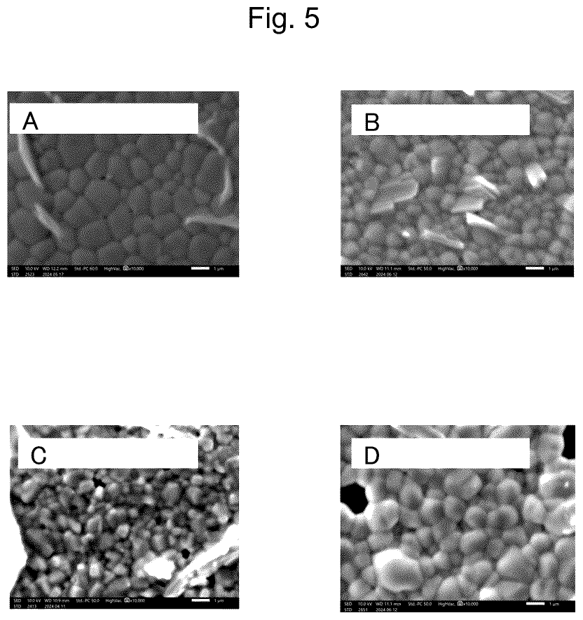

FIG. 5 shows SEM photographs of the perovskite films treated in a high temperature test. In the drawing, A is a SEM photograph of a perovskite film manufactured using a precursor solution including an additive having 8 carbon atoms in a side-chain alkyl group (that is, n is 7), B is a SEM photograph of a perovskite film manufactured using a precursor solution including an additive having 16 carbon atoms in a side-chain alkyl group (that is, n is 15), C is a SEM photograph of a perovskite film manufactured using a precursor solution including an additive having 4 carbon atoms in a side-chain alkyl group (that is, n is 3), and D is a SEM photograph of a perovskite film manufactured using a precursor solution including an additive having 6 carbon atoms in a side-chain alkyl group (that is, n is 5).

As illustrated in FIG. 5, no remarkable change occurred even by the treatment of the high temperature test in the perovskite films manufactured using the precursor solutions including the additives having 7 or more carbon atoms in the side-chain alkyl groups (that is, n is 6 or more) (Panel A and B). In contrast to this, the perovskite particles were polysized by the treatment of the high temperature test and vacancies were generated in the perovskite films manufactured using the precursor solutions including the additives having less than 7 carbon atoms in the side-chain alkyl groups (that is, n is less than 6) (Panel Cand D). This is estimated to be caused by uneven heat conduction between the particles because the perovskite particles included in the perovskite films at the beginning of manufacturing had uneven particle sizes.

FIG. 6 shows an orientation index of each plane index in the XRD calculated using the Wilson's method. In the drawing, the horizontal axis indicates the plane index, and the vertical axis indicates the orientation index of each plane index.

As illustrated in FIG. 6, in the perovskite film manufactured using the additive having 8 carbon atoms in the side-chain alkyl group (that is, n is 7), orientation indices on at least a (100) plane, a (002) plane, and a (220) plane among the orientation indices in the XRD calculated using the Wilson's method were 1 or more.

FIG. 7 shows a relationship between the carbon number of the side-chain alkyl group in the additive used in manufacturing the perovskite film and the XRD area ratio (PbI₂/PVK) of the (001) plane peak of the PbI₂ and the (110) plane peak of the α phase of the PVK in the manufactured perovskite film. In the drawing the horizontal axis indicates the carbon number of the side-chain alkyl group and the vertical axis indicates the XRD area ratio (PbI₂/PVK).

As illustrated in FIG. 7, in the perovskite film manufactured using the additive having 3 or more carbon atoms in the side-chain alkyl group (that is, n is 2 or more), the XRD area ratio (PbI₂/PVK) was 0.

FIG. 8 shows a relationship between a temperature of the heat treatment test of the perovskite film manufactured without an additive (comparative) or using the additive having 8 carbon atoms in the side-chain alkyl group (that is, n is 7) and the XRD area ratio (PbI₂/PVK) of the (001) plane peak of the PbI₂ and the (110) plane peak of the α phase of the PVK included in the perovskite film after the treatment. In the drawing the horizontal axis indicates the temperature (° C.) of the heat treatment test and the vertical axis indicates the XRD area ratio (PbI₂/PVK).

As illustrated in FIG. 8, in the comparative perovskite film manufactured without an additive, the perovskite film after the treatment at 25° C. has the XRD area ratio (PbI₂/PVK) of 0.4, and the XRD area ratio (PbI₂/PVK) also increased in accordance with the elevation of the treatment temperature. In contrast to this, in the perovskite film manufactured using the additive having 8 carbon atoms in the side-chain alkyl group (that is, n is 7), the XRD area ratios (PbI₂/PVK) were 0 at all the treatment temperatures of 25° C., 80° C. and 90° C.

The perovskite photovoltaic cell having the perovskite film including the α phase of the perovskite compound as the photoelectric conversion layer is known to be high in conversion efficiency. In such a perovskite photovoltaic cell, when the perovskite compound included in the perovskite film is decomposed by heat, humidity, light irradiation, and/or the like, the PbI₂ is generated. In view of this, the XRD area ratio (PbI₂/PVK) of the (001) plane peak of the PbI₂ and the (110) plane peak of the α phase of the PVK included in the perovskite film has a constant correlation relationship with an amount of the PbI₂ generated by decomposition of the perovskite compound, and therefore, can not only serve as a deterioration index of the perovskite film or the perovskite compound used in the perovskite photovoltaic cell, but can also serve as a performance index of the perovskite photovoltaic cell. For example, when the XRD area ratio (PbI₂/PVK) in the perovskite film or the perovskite compound is small, a generation amount of the PbI₂ is estimated to be small. In this case, the perovskite film or the perovskite compound can be determined to have a small deterioration degree. The perovskite photovoltaic cell having the perovskite film as the photoelectric conversion layer can be determined to have a satisfactory performance.

Sizes of the crystal particles of the perovskite-type crystals can affect the power generation efficiency of the perovskite photovoltaic cell. The reason is that the lattice defects present in the interfaces (grain boundaries) on the surfaces of the plurality of perovskite-type crystals serve as a trap of electrons and/or holes, cause recombination, and lower the power generation efficiency. Accordingly, increasing the particle sizes of the perovskite-type crystal particles reduces specific surface areas of the crystal particles to reduce the areas of the grain boundaries, and as the result, the power generation efficiency of the perovskite photovoltaic cell can be improved. When the particle size of the perovskite-type crystal particle exceeds 1 μm, the grain boundary is generated only in a thickness direction of the perovskite film and not generated in the plane direction, and therefore, the effect of the presence of the grain boundary defect blocking charge transfer can be reduced. Thus, in order to improve the power generation efficiency of the perovskite photovoltaic cell, it is effective to increase the particle size of the perovskite-type crystal particle. In order to improve the durability of the perovskite photovoltaic cell, it is effective to improve the stability of the crystal particles such that the particle size of the perovskite-type crystal particle and/or the crystalline structure does not substantially change under the high temperature test condition.

Generally, crystallization is constituted of respective steps of nucleus formation, grain growth, coalescence, and crystallization. The steps of the nucleus formation and the coalescence (Ostwald ripening) are important to control the particle size of the crystal among those. The Ostwald ripening is a coalescence mechanism in which small particles have different radii, thus having different ambient vapor pressures, and therefore, the larger nuclei grow taking in the smaller nuclei to continue to grow until all the small nuclei are gone. In the preparation of the perovskite-type crystal by the poor solvent method, the vaporization speed of the poor solvent is slow, and therefore, the Ostwald ripening easily occurs during annealing. In the Ostwald ripening, many small particles (nuclei) are present in the initial state, and therefore, the nucleus formation control of the perovskite-type crystals by addition of the additive as the ionic liquid is important.

In the additive represented by Formula (I), generally, a polar part (a methylimidazolium ring and a chlorine ion) and a non-polar part (the side-chain alkyl group) each form a domain structure. The domain structure forms an intermolecular network of the additive represented by Formula (I). As illustrated in FIG. 2, the additive having 8 carbon atoms in the side-chain alkyl group (that is, n is 7) exhibited the local minimal melting point. As illustrated in FIG. 3, the perovskite particles included in the perovskite film manufactured using the additive having 8 carbon atoms in the side-chain alkyl group (that is, n is 7) exhibited the average particle size of 1.65±0.604 μm that is the local maximal value. From these results, in the preparation of the perovskite-type crystal using an additive having 8 carbon atoms in the side-chain alkyl group (that is, n is 7), the additive and the precursor substance are assumed to interact closely at the atomic level, thus allowing for a large number of uniform nuclei, and consequently, Ostwald ripening is presumed to be promoted. In such a reaction system, the domain structure of the additive forms the intermolecular network, by which the system is stabilized electrically and sterically, and as the result, it is estimated that a large number of highly symmetric, large-grain perovskite-type crystals can be obtained. The perovskite photovoltaic cell having the perovskite film including the perovskite-type crystals with large particle sizes thus obtained as the photoelectric conversion layer is estimated to have high durability.

The present disclosure is not limited to the examples described above and includes various modifications. For example, the examples described above have been described in detail to facilitate understanding of the present disclosure and are not necessarily limited to those having all the described configuration. It is also possible to add, delete, and/or replace parts of the configuration of each example with another configuration.

### DESCRIPTION OF SYMBOLS

100 Perovskite photovoltaic cell
11 Substrate
12a First electrode
12b Second electrode
13a First carrier transport layer
13b Second carrier transport layer
14 Photoelectric conversion layer

What is claimed is:

1. A method for manufacturing a perovskite photovoltaic cell, comprising:
an application step of applying a precursor solution on a carrier transport layer, the precursor solution including a precursor substance that generates a perovskite-type crystal, an additive represented by Formula (I): 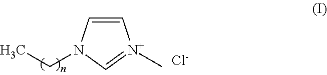
wherein n is an integer equal to or more than 6, and
a solvent; and
a heating step of performing a heat treatment on a precursor layer obtained in the application step to form a photoelectric conversion layer including a perovskite film.

2. The method according to claim 1,
wherein n is an integer equal to or more than 6 and equal to or less than 11.

3. The method according to claim 1,
wherein n is 7.

4. The method according to claim 1,
wherein the precursor substance is a mixture of a halogenated organic amine, a halogenated amidinium, and a metal halide.

5. The method according to claim 4,
wherein the precursor substance is a mixture of methylammonium iodide, formamidinium iodide, cesium iodide, and lead iodide.

6. A perovskite photovoltaic cell at least comprising:
a photoelectric conversion layer including a perovskite film including a perovskite-type crystal; and
two carrier transport layers arranged on both surfaces of the photoelectric conversion layer,
wherein the perovskite film included in the photoelectric conversion layer has orientation indices on at least a (100) plane, a (002) plane, and a (220) plane among orientation indices in an X-ray diffraction (XRD) calculated using Wilson's method of 1 or more.
